(19) United States
(12) Patent Application Publication
(10) Pub. No.: US 2026/0003157 A1
(43) Pub. Date: Jan. 1, 2026

(54) ADAPTIVE OPTICAL ELEMENT HAVING AN INSERTION ELEMENT

(71) Applicant: Carl Zeiss SMT GmbH, Oberkochen (DE)

(72) Inventor: Dieter BADER, Goeggingen (DE)

(21) Appl. No.: 19/317,202

(22) Filed: Sep. 3, 2025

Related U.S. Application Data
(63) Continuation of application No. PCT/EP2024/056473, filed on Mar. 12, 2024.

(30) Foreign Application Priority Data
Mar. 15, 2023 (DE) 10 2023 202 339.3

(51) Int. Cl. G02B 7/182; G03F 7/00

(52) U.S. Cl. CPC G02B 7/1821; G03F 7/70266

(57) ABSTRACT

An adaptive optical element for a microlithographic projection exposure apparatus, comprising: a substrate; an optically effective surface; and at least one solid-state actuator for at least partial deflection or deformation of the optically effective surface. At least one bore extends through at least regions of the substrate. An insertion element comprises the at least one solid-state actuator. The insertion element is in the bore so that the at least one solid-state actuator is affixed at a predetermined position within the bore.

### CROSS-REFERENCE TO RELATED APPLICATIONS

The present application is a continuation of, and claims benefit under 35 USC 120 to, international application No. PCT/EP2024/056473, filed Mar. 12, 2024, which claims benefit under 35 USC 119 of German Application No. 10 2023 202 339.3, filed Mar. 15, 2023. The entire disclosure of each of these applications is incorporated by reference herein.

### FIELD

The disclosure relates to an adaptive optical element, such as an adaptive mirror or a lens element, for a microlithographic projection exposure apparatus, having a substrate, an optically effective surface for exposure to electromagnetic radiation, and at least one solid-state actuator for at least partial deflection or deformation of the optically effective surface.

### BACKGROUND

Projection exposure apparatuses are used for producing extremely fine structures, such as on semiconductor components or other microstructured component parts. Operation of the apparatuses involves the production of extremely fine structures down to the order of nanometers by way of generally reducing imaging of structures on a mask, a so-called reticle, on an element to be structured, a so-called wafer, that is provided with photosensitive material. The minimum dimensions of the structures produced are, in general, directly dependent on the wavelength of the light used. The light can be shaped for the optimum illumination of the reticle in an illumination optics unit. Recently, light sources having an emission wavelength in the order of a few nanometers, for example between 1 nm and 120 nm, such as in the order of 13.5 nm, have increasingly been used. The described wavelength range is also referred to as the EUV range.

Apart from with the use of systems which operate in the EUV range, the microstructured component parts are also produced using commercially established DUV systems, which have a wavelength of between 100 nm and 300 nm, such as 193 nm. The desire to be able to produce smaller and smaller structures has increased the desired properties of optical correction in the systems. There is generally an increase in the throughput of each new generation of projection exposure apparatuses in the EUV range or DUV range so as to increase the profitability. This typically leads to a greater thermal load and hence to more imaging aberrations caused by the heat.

In order to at least partially compensate for these issues and also generally to increase the image position accuracy and image quality (both along the optical axis, or in the light propagation direction, and in the lateral direction, or perpendicular to the optical axis or light propagation direction), it is known to design one or more mirrors in the optical system as an adaptive mirror with at least one actuator, such as a solid-state actuator made of a piezoelectric material or ferroelectric material or electrostrictive material or magnetostrictive material, wherein for example an electric field of locally varying strength is generated across the piezoelectric layer by applying a voltage to electrodes arranged on both sides of the piezoelectric layer. In the case of a local deformation of the piezoelectric layer, the optically effective surface of the adaptive element also deforms, with the result that imaging aberrations may be compensated for at least in part—by way of an appropriate (possibly also temporally variable) control of the electrodes. The deformation of the optically effective surface may also generally be used to further optimize the microlithographic imaging process.

The solid-state actuators are usually fastened to the adaptive optical element. An adhesive is usually used to this end, wherein in the case of an adaptive mirror, the actuator arrangement is arranged between a mirror substrate and a reflection layer system or an intermediate layer and fastened using an adhesive. In this case, the adaptive mirror is usually produced layer by layer. The production of such an adaptive optical element is typically complex and can be prone to errors. Since the solid-state actuators themselves also often have high mechanical and electrical tolerances, these are usually compensated for with much effort by the joining process. Moreover, the joining process itself may also lead to deviations, for example due to the use of different amounts of the utilized adhesive, a different adhesive application, differing adhesive gaps, the absorption of moisture into the adhesive, etc. The specifications and for example the maximum travel of the solid-state actuators may also change over the service life of the optical element on account of additional moisture absorption or moisture release.

Such adaptive mirrors are known from, for example, DE 10 2016 209 847 A1, EP 1 191 377 B1 or DE 10 2017 208364 A1.

### SUMMARY

In an aspect, the disclosure provides an adaptive optical element for a microlithographic projection exposure apparatus. The adaptive optical element has a substrate, an optically effective surface, and at least one solid-state actuator for at least partial deflection or deformation of the optically effective surface. At least one bore extends through the substrate at least in regions. An insertion element comprises the at least one solid-state actuator. The insertion element is both designed and received in the bore such that the at least one solid-state actuator is arranged and affixed at a predetermined position within the bore.

The at least one solid-state actuator can be arranged and affixed, for example, by bonding, at a predetermined position within the bore. The bore, embodied as a long bore for example, can provide a space with defined dimensions, in which the solid-state actuators can be received. Mechanical deviations of the solid-state actuators can thus have a lesser effect. From a process-technological point of view, the actuators can be received more easily via the insertion element comprising at least one solid-state actuator since the configuration, for example the length of the insertion element, defines the position of the solid-state actuator within the bore. The solid-state actuator may also be formed as an actuator stack having multiple interconnected solid-state actuator elements. The solid-state actuator or solid-state actuator elements may be formed of piezoelectric or electrostrictive or magnetostrictive or ferroelectric material.

The insertion element or each of the insertion elements may be formed by exactly one solid-state actuator, the dimension of which is approximately matched to the depth of the bore in which it is received, i.e. approximately corresponds to the depth of the bore. In this case, the solid-state actuator may also be formed as an actuator stack having multiple interconnected solid-state actuator elements. Optionally, the dimensions of the actuator stack are then matched to the dimensions of the bore, such as to its depth.

Alternatively, the insertion element can comprise at least one spacer that is connected to the at least one solid-state actuator. In this context, the spacer may also be formed as a printed circuit board or as a flexboard. Moreover, a passage in which the electrical connectors of the solid-state actuators are arranged may be formed in the spacer. The insertion element may comprise any desired number of spacers. For example, the insertion element may comprise a spacer at the ends or at least at one of the ends.

Furthermore, the insertion element can comprise multiple solid-state actuators or multiple actuator stacks, with two adjacent solid-state actuators/actuator stacks in each case being connected to each other via a spacer. This can help allow a plurality of solid-state actuators to be received in the adaptive optical element and be positioned in a simple and reproducible manner at the predetermined positions.

It can be desirable for at least individual spacers or all spacers to be formed flexibly. This can help allow compensation of any potential manufacturing tolerances during the production of the insertion element and the bore. Moreover, the insertion element and hence the solid-state actuators may be more robust and durable as a result.

The length of the insertion element can be matched to the depth of the bore. Thus, it is possible to define the length of the insertion element and also the position of the individual solid-state actuators within the bore by varying the number of spacers and/or their dimensions (such as their lengths) and/or by varying the number of solid-state actuators and/or their dimensions (such as in the longitudinal extent of the bore). In one embodiment, the length of the insertion element approximately can correspond to the depth of the bore. In another embodiment, it can be desirable for the length of the insertion element to be shorter than the depth of the bore.

In an alternative to that or in addition, the insertion element may be formed as a sleeve in which the at least one solid-state actuator is arranged. The sleeve may be made of a metal and comprise EDM cuts. This can help facilitate receiving and positioning of the solid-state actuators or actuator stacks within the bore and increases the robustness of the insertion element.

In an alternative to that or in addition, the insertion element may also be formed as a rail or spoke on which the at least one solid-state actuator or the plurality of solid-state actuators/actuator stacks are attached in a spaced apart manner.

The at least one bore may extend as desired within the substrate. In order to cause a sufficient and controlled deformation of the optically effective surface, it can be desirable for the at least one bore to extend approximately parallel to the optically effective surface at least in regions within the substrate.

Alternatively, however, depending on the embodiment of the adaptive optical element and of the optically effective surface for example, it can be desirable for the at least one bore to extend tangentially to the optically effective surface at least in regions within the substrate. Likewise, a plurality of bores may be formed radially with respect to the optically effective surface.

The profile of the at least one bore can be at least partly matched to the contour of the substrate or the optically effective surface.

To simplify the supply of the bonding mechanism and hence to simplify the fixation of the insertion element and/or the solid-state actuators on the inner surface of the bore, at least one access bore fluid-connected to the at least one bore can be present for feeding the bonding mechanism into the bore. The bonding mechanism can be an adhesive, such as consisting of epoxy resin or comprising epoxy resin. Furthermore, the number of access bores present can be matched to the number of solid-state actuators or to the number of actuator stacks.

In order to prevent the absorption or discharge of liquid once the insertion element has been received in the at least one bore, i.e. in order to create a closed system, all bores (i.e. the access bores and the bores) can be sealed in liquid-tight and/or gas-tight fashion. For example, this may be implemented via a sealing mechanism, such as a closure or plug, for example made of glass.

Alternatively, a stable system may also be created by virtue of at least one media opening fluid-connected to the at least one bore being present for feeding a gas, such as air, or a fluid into the bore. By supplying a constant flow of air or gas, the moisture within the adaptive optical element can be kept constant. In this case, at least two media openings fluid-connected to the bore can be present in each bore. Any spacers potentially present may also have recesses for the media guide.

In order to reduce mechanical stresses in the substrate, cutouts may be formed in the substrate adjacent to the openings in the substrate, i.e. the bores, any access bores present and media openings. This can also reduce effects such as adhesive shrinkage or the expansion of adhesive or the substrate.

The at least one bore or at least one of the bores may be formed as a blind hole or as a through-hole that extends through the substrate. A first portion of the bores may also be formed as blind holes, and a second portion of the bores may be formed as through-holes.

For example, it can be desirable for a plurality of bores to be present and extend through at least regions of the substrate in a manner spaced apart from one another, and an insertion element comprising at least one solid-state actuator is received in each of the bores. In this case, the direction of extent of the bores may be formed as desired within the substrate.

Moreover, in order to create an actuator lattice, a first layer having a plurality of first bores with insertion elements received therein and, adjacent to the first layer, a second layer having a plurality of second bores with insertion elements received therein can be present, that the direction of extent of the first bores can deviate from the direction of extent of the second bores. This can also help to enable a flat and, for example, well-controllable deformation of the optically effective surface. The direction of extent of the first bores can be perpendicular to the direction of extent of the second bores in this case.

Further features, properties and aspects of the present disclosure are described in more detail below on the basis of embodiments and embodiments variants and with reference to the appended figures. In this respect, various features described herein are, in general, adaptable both individually and in any desired combination. The embodiments and embodiment variants described below are merely examples which, however, do not limit the subject matter of the disclosure.

### BRIEF DESCRIPTION OF THE FIGURES

In the figures:

FIG. 1A shows a schematic illustration of a microlithographic projection exposure apparatus designed for operation in the EUV;

FIG. 1B shows a schematic illustration of a microlithographic projection exposure apparatus designed for operation in the DUV;

FIG. 2 shows a schematic illustration of a first exemplary embodiment of an adaptive optical element in the form of an adaptive mirror;

FIG. 3 shows a schematic illustration of a second exemplary embodiment of an adaptive optical element in the form of an adaptive mirror;

FIG. 4 shows a schematic illustration of a third exemplary embodiment of an adaptive optical element in the form of an adaptive mirror;

FIG. 5 shows a schematic illustration of a fourth exemplary embodiment of an adaptive optical element in the form of an adaptive mirror; and

FIG. 6 shows a schematic illustration of a fifth exemplary embodiment of an adaptive optical element in the form of an adaptive mirror.

### DETAILED DESCRIPTION

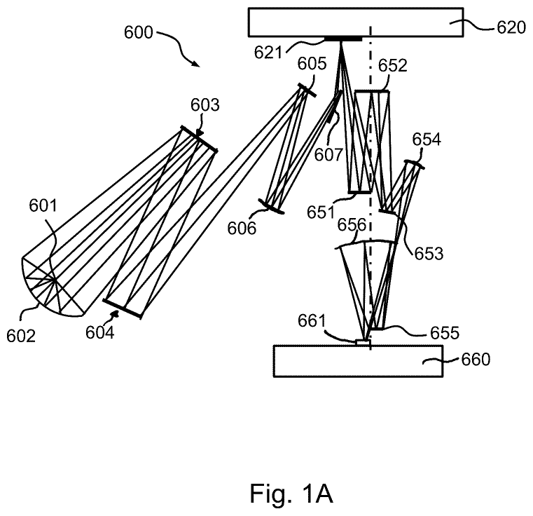

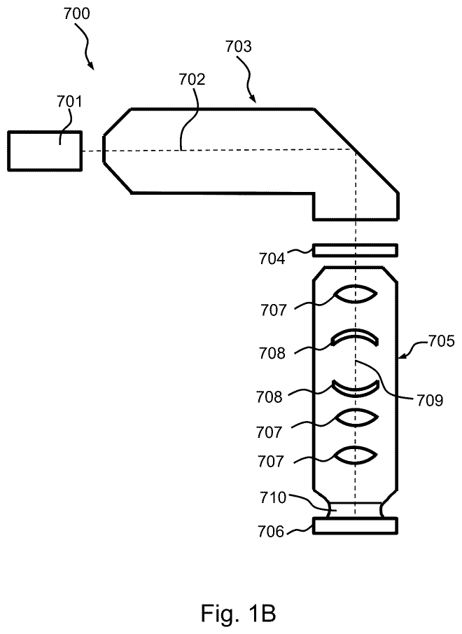

FIG. 1A shows a schematic illustration of an exemplary projection exposure apparatus 600 designed for operation in the EUV, in which the present disclosure is implementable, i.e. in which the actuator 100 according to the disclosure can be used. However, the disclosure can also be used in other nanopositioning systems.

According to FIG. 1A, an illumination device in a projection exposure apparatus 600 designed for EUV comprises a field facet mirror 603 and a pupil facet mirror 604. The light from a light source unit comprising a plasma light source 601 and a collector mirror 602 is steered to the field facet mirror 603. A first telescope mirror 605 and a second telescope mirror 606 are arranged downstream of the pupil facet mirror 604 in the light path. Arranged downstream in the light path is a deflection mirror 607, which steers the radiation incident thereon to an object field in the object plane of a projection lens comprising six mirrors 651-656. At the location of the object field, a reflective structure-bearing mask 621 is arranged on a mask stage 620 and with the aid of the projection lens is imaged into an image plane, in which a substrate 661 coated with a light-sensitive layer (photoresist) is situated on a wafer stage 660. One or more of the mirrors of the projection exposure apparatus 600 designed for EUV may be formed as the adaptive optical element 100 according to the disclosure.

The disclosure can likewise be used in a DUV apparatus, as illustrated in FIG. 1B. A DUV apparatus is set up in principle like the above-described EUV apparatus from FIG. 1A, wherein mirrors and lens elements can be used as optical elements in a DUV apparatus and the light source of a DUV apparatus emits used radiation in a wavelength range of 100 nm to 300 nm.

The DUV lithography apparatus 700 illustrated in FIG. 1B has a DUV light source 701. For example, an ArF excimer laser that emits radiation 702 in the DUV range at for example 193 nm may be provided as the DUV light source 701. A beam shaping and illumination system 703 guides the DUV radiation 702 onto a photomask 704. The photomask 704 is embodied as a transmissive optical element and can be arranged outside the systems 703. The photomask 704 has a structure which is imaged onto a wafer 706 or the like in a reduced fashion via the projection system 705. The projection system 705 comprises a plurality of lens elements 707 and/or mirrors 708 for imaging the photomask 704 onto the wafer 706. In this case, individual lens elements 707 and/or mirrors 708 of the projection system 705 can be arranged symmetrically with respect to the optical axis 709 of the projection system 705. It should be noted that the number of lens elements 707 and mirrors 708 of the DUV lithography apparatus 700 is not restricted to the number illustrated. A greater or lesser number of lens elements 707 and/or mirrors 708 may also be provided. For example, the beam shaping and illumination system 703 of the DUV lithography apparatus 700 comprises a plurality of lens elements 707 and/or mirrors 708. Furthermore, the mirrors are generally curved on their front side for beam shaping purposes. An air gap 710 between the last lens element 707 and the wafer 706 can be replaced by a liquid medium having a refractive index of >1. The liquid medium can be high-purity water, for example. Such a construction is also referred to as immersion lithography and has an increased photolithographic resolution. The adaptive optical element 100 according to the disclosure can be used for deforming the mirrors or lens elements in the DUV lithography apparatus 700, such as in the projection system 705 thereof.

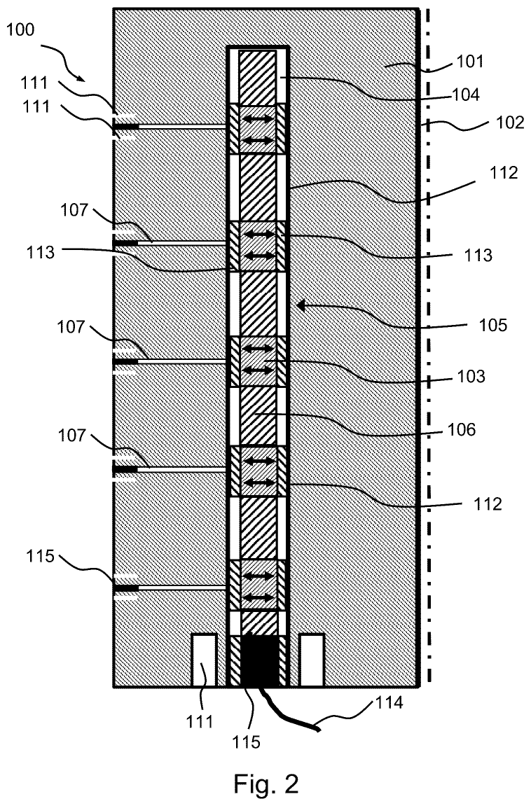

FIG. 2 shows an optical element 100 according to the disclosure, formed as an adaptive mirror for a microlithographic projection exposure apparatus 600, 700 and having a substrate 101 and an optically effective surface 102 for exposure to electromagnetic radiation. At least one bore 104, in which an insertion element 105 is received, is formed in the substrate 101. The insertion element 105 comprises a plurality of solid-state actuators 103—five actuator stacks connected in series in the present case—each having a plurality of interconnected solid-state actuator elements stacked one above the other. The solid-state actuators 103 are formed as piezo actuators but may also be formed from electrostrictive, magnetostrictive or ferroelectric material. Two solid-state actuators 103 or actuator stacks are connected to each other via a spacer 106 in each case and together with the additional spacers 106 formed at the ends form the insertion element 105 in the present case. The bore 104 is formed as a blind hole in the present case but may also be formed as a through-hole that extends through the substrate 101. In this case, the length of the insertion element 105 may be influenced or defined by the number and/or the dimensions of the solid-state actuators/actuator stacks 103 utilized (such as their length along the longitudinal extent of the bore 104) and/or by the number and/or the dimensions of the spacers 106 (such as their length along the longitudinal extent of the bore 104). In this case, the length of the insertion element 105 can be matched to the depth of the bore 104, with the sum of the length of the insertion element 105 and of a sealing mechanism 115 that seals off the bore 104 approximately corresponding to the depth of the bore 104 in the present case.

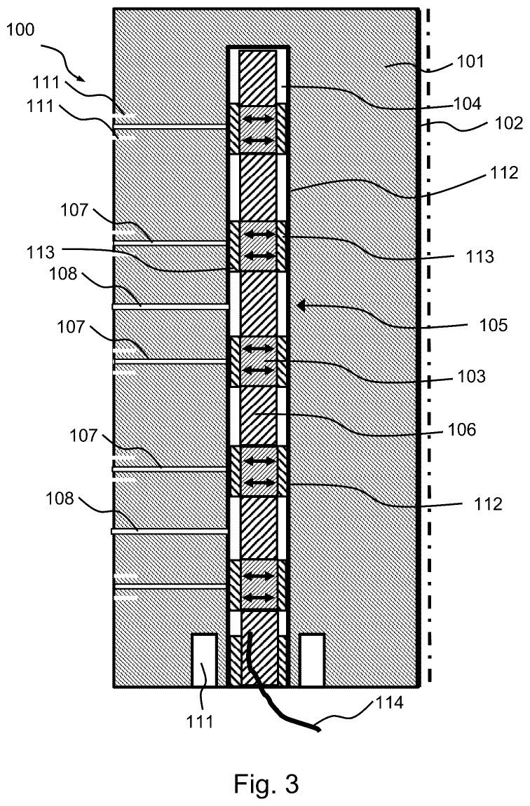

The spacers 106 may be rigid or flexible, for example as printed circuit boards or flexboards. The electrical connectors 114 of the solid-state actuators 103 may also be introduced into a through-opening (not depicted in detail) that is formed in the spacer 106. As depicted in FIG. 3, the insertion element 105 is affixed to the inner wall of the bore 104 via a bonding mechanism 113, i.e. an adhesive. In this case, the bonding mechanism 113 can be added via an access bore 107 that is fluid-connected to the bore 104.

In the present case, each solid-state actuator stack 103 is assigned a respective access bore 107 connected to the bore 104. In the present case, both the bore 104 and the access bores 107 are sealed, at least fluid-tightly, via a sealing mechanism 115, for example a closure or plug, such as a plug made of glass or steel. The plug can have approximately the same coefficient of thermal expansion (CTE). The solid-state actuators 103 may have any desired direction of actuation. In the present case there are solid-state actuators 103 that allow a surface-normal actuation with respect to the optically effective surface 102; however, it is also possible to use solid-state actuators 103 that actuate in surface-parallel fashion with respect to the optically effective surface 102 or else solid-state actuators 103 that actuate in any direction. Deflection of the solid-state actuators 103 causes a deformation of the substrate 101 and hence of the optically effective surface 102, at least in regions. In order to counteract material stresses, cutouts 111 are also present in the substrate 101 in addition to the bores 103. Furthermore, at least in regions but optionally in full, the inner wall of the bore is coated with a protective layer 112 that absorbs light in the UV wavelength range.

From a process-technical point of view, inserting the solid-state actuators 103 into the bore 104 and setting the position of the respective solid-state actuator/actuator stack 103 within the bore 104 to a predetermined position are facilitated by the insertion element 105. In addition, mechanical deviations of the individual solid-state actuators 103 and hence of the actuator stack can be compensated by the bore 104. Furthermore, an actuator replacement in the adaptive optical element 100 is facilitated by the insertion element 105.

In an alternative to the exemplary embodiment shown in FIG. 3, the insertion element 105 may also be formed as a sleeve in which the solid-state actuators 103 or the solid-state actuators 103 and the spacers 106 are received. Alternatively, the insertion element 105 may also be formed as a rail or a spoke, to which at least one solid-state actuator/solid-state actuator stack 103 and optionally at least one spacer 106 are attached. In addition, it is also possible that the insertion element 105 is formed from exactly one solid-state actuator 103 or exactly one actuator stack. The exemplary embodiment shown in FIG. 3 can have a plurality of bores 104 extending in the substrate, with insertion elements 105 being received and affixed in at least some of the bores 104.

FIG. 3 shows a second exemplary embodiment of the adaptive optical element 100 in the form of an adaptive mirror. The access bores 107 are open. In order to nevertheless keep the moisture in the adaptive optical element 100 constant, at least one media opening and optionally multiple media openings 108 are present for supplying air or a gas or a fluid into the bore. In the present case, the spacers 106 also have through-openings (not depicted in more detail) for guiding the flow of media along the bore 104. In the exemplary embodiment depicted in FIG. 3, the length of the insertion element 105 corresponds at least approximately to the depth of the bore. However, the bore 104 may optionally also be sealed with a sealing mechanism 115.

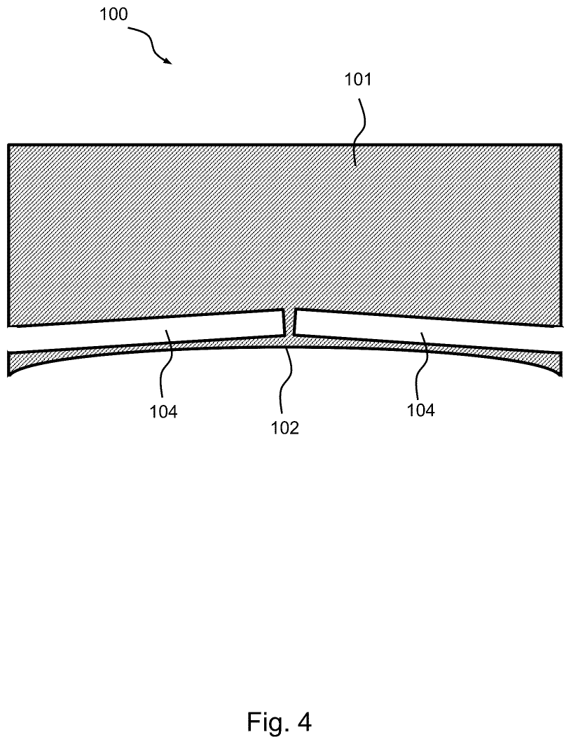

In the exemplary embodiments according to FIGS. 2 and 3, the at least one bore 104 extends parallel to the optically effective surface 102. FIG. 4 shows an embodiment with a plurality of bores 104, with the bores 104 extending through the substrate 101 in a straight line that makes an angle not equal to 180° with the optically effective surface 102. Insertion elements 105 (not shown in detail) with at least one solid-state actuator 103 are in each case received in the bores 104. Furthermore, the bore 104 may also be designed in such a way that it is designed tangentially vis-à-vis a point on the optically effective surface 102 and extends straight through a region of the mirror body 101. In this context, it can be desirable for the point to correspond approximately to the center of the longitudinal extent of the bore 104.

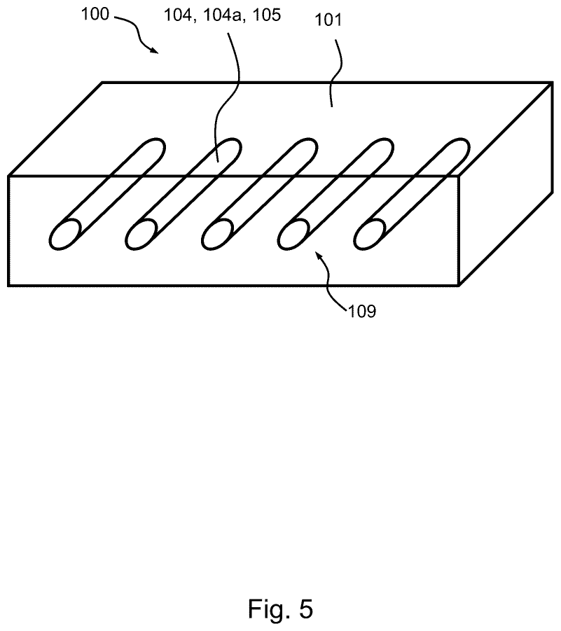

The exemplary embodiment according to FIG. 5 shows an adaptive optical element 100 having a plurality of bores 104 that extend through the mirror substrate at least in regions and that are spaced apart from each other. Insertion elements 105 (not depicted in detail) are received in the bores 104 or at least in some of the bores 104. The individual insertion elements 105 may either all be formed the same or differ terms of the number and/or dimension of the solid-state actuators 103 and/or in terms of the number and/or dimension of the spacers 106.

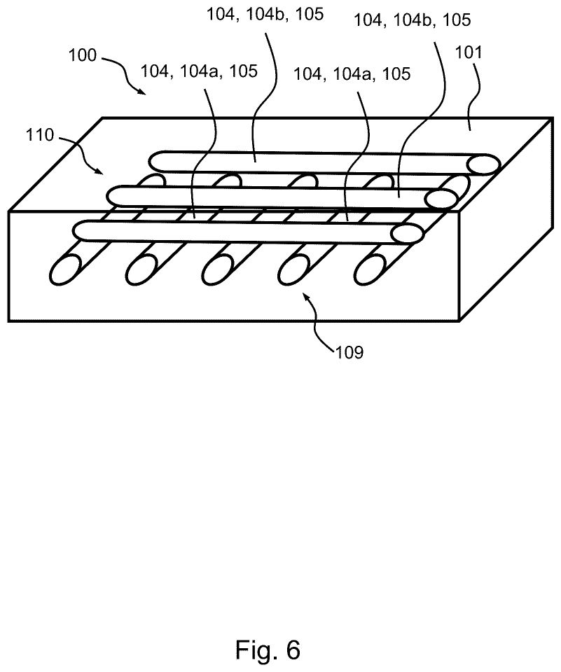

The exemplary embodiment in FIG. 6 differs in terms of the fact that a first layer 109 having a plurality of first bores 104a with insertion elements 105 received therein and, adjacent to the first layer 109, a second layer 110 with a plurality of second bores 104b with insertion elements 105 received therein are present, and that the direction of extent of the first bores 104a deviates from the direction of extent of the second bores 104b, being perpendicular thereto in the present case. More than two layers may also be present in the substrate 101. In the process, the directions of extent may correspond to one another or differ from one another.

The adaptive optical elements 100 of FIGS. 5 and 6 are depicted in a highly simplified manner; the features described in FIGS. 2, 3 and 4 are also transferable to the exemplary embodiments described in FIGS. 5 and 6.

### LIST OF REFERENCE SIGNS

100 Adaptive mirror
101 Substrate
102 Optically effective surface
103 Solid-state actuator
104 Bore
104a First bore
104b Second bore
105 Insertion element
106 Spacer
107 Access bore
108 Media opening
109 First layer
110 Second layer
111 Cutout
112 Protective layer
113 Bonding mechanism
114 Electrical connectors
115 Sealing mechanism
600 Projection exposure apparatus
601 Plasma light source
602 Collector mirror
603 Field facet mirror
604 Pupil facet mirror
605 First telescopic mirror
606 Second telescopic mirror
607 Deflection mirror
620 Mask stage
621 Mask
651 Mirror (projection lens)
652 Mirror (projection lens)
653 Mirror (projection lens)
654 Mirror (projection lens)
655 Mirror (projection lens)
656 Mirror (projection lens)
660 Wafer stage
661 Coated substrate
700 DUV lithography apparatus
701 DUV light source
702 DUV radiation/beam path
703 Beam shaping and illumination system (DUV)
704 Photomask
705 Projection system
706 Wafer
707 Lens element
708 Mirror
709 Optical axis

What is claimed is:

1. An adaptive optical element, comprising:
a substrate having a bore therein;
an optically effective surface; and
an insertion element in the bore, the insertion element comprising a solid-state actuator configured to at least partial deflect or at least partially deform the optically effective surface,
wherein at least portions of the bore extend approximately parallel or tangentially to the optically effective surface.

2. The adaptive optical element of claim 1, wherein the insertion element comprises a spacer connected to the solid-state actuator.

3. The adaptive optical element of claim 2, wherein the spacers is flexible.

4. The adaptive optical element of claim 1, wherein:
the insertion element comprises a plurality of solid-state actuators and a plurality of spacers; and
for a pair of adjacent solid-state actuators, a spacer connects the solid-state actuators.

5. The adaptive optical element of claim 4, wherein the spacers are flexible.

6. The adaptive optical element of claim 1, wherein a length of the insertion element is the same as a length of the bore.

7. The adaptive optical element of claim 1, wherein:
the insertion element comprises a sleeve in which the solid-state actuator is disposed; or
the insertion element comprises a rail to which solid-state actuator is attached.

8. The adaptive optical element of claim 1, further comprising an access bore fluid-connected to the bore.

9. The adaptive optical element of claim 1, wherein the bore is sealed in a liquid-tight fashion and/or a gas-tight fashion.

10. The adaptive optical element of claim 1, comprising a media opening configured to feed a gas or a fluid into the bore.

11. The adaptive optical element of claim 1, wherein a length of the insertion element is matched to a depth of the bore.

12. The adaptive optical element of claim 1, wherein the bore is a blind hole in the substrate.

13. The adaptive optical element of claim 1, wherein the bore is a through-hole extending through the substrate.

14. The adaptive optical element of claim 1, comprising a plurality of bores and a plurality of insertion elements, wherein:
an insertion element is in each bore;
each bore extends through at least regions of the substrate;
the bores are spaced apart from one another; and
each insertion element comprises a solid-state actuator.

15. The adaptive optical element of claim 1, comprising a plurality of first and second bores and a plurality of first and second insertion elements, wherein:
the substrate comprises a first layer and a second layer adjacent to the first layer;
the first layer comprises the plurality of first bores;
a first insertion element is disposed in each first bore;
the second layer comprises the plurality of second bores;
a second insertion element is disposed in each second bore; and
a direction of extent of the first bores is different from a direction of extent of the second bores.

16. An apparatus, comprising:
an adaptive optical element according to claim 1,
wherein the apparatus is a microlithographic projection exposure apparatus.

17. A method of using a microlithographic projection exposure apparatus comprising an illumination device and a projection lens, the method comprising:
using the illumination device to illuminate an object field; and
using the projection lens to project the illuminated object field into an image field,
wherein the microlithographic projection exposure apparatus comprises an adaptive optical element according to claim 1.

18. An adaptive optical element, comprising:
a substrate having a bore therein;
an optically effective surface; and
an insertion element in the bore, the insertion element comprising a plurality of solid-state actuators or a plurality of solid state actuator elements.

19. An apparatus, comprising:
an adaptive optical element according to claim 18,
wherein the apparatus is a microlithographic projection exposure apparatus.

20. A method of using a microlithographic projection exposure apparatus comprising an illumination device and a projection lens, the method comprising:
using the illumination device to illuminate an object field; and
using the projection lens to project the illuminated object field into an image field,
wherein the microlithographic projection exposure apparatus comprises an adaptive optical element according to claim 18.
